(19) United States
(12) Patent Application Publication
(10) Pub. No.: US 2003/0107042 A1
(43) Pub. Date: Jun. 12, 2003

(54) Organic electroluminescent device with a containing fluorine inorganic layer

(75) Inventors: En-Chung Chang, Yun-Lin Hsien (TW); Ching-Ian Chao, Hsin-Chu Hsien (TW); Peng-Yu Chen, Taichung Hsien (TW); Chia-Fen Hsieh, Tainan (TW)

Correspondence Address: BACON & THOMAS, PLLC, 625 SLATERS LANE, FOURTH FLOOR, ALEXANDRIA, VA, 22314

(73) Assignee: Industrial Technology Research Institute, Hsien (TW)

(21) Appl. No.: 10/121,589

(22) Filed: Apr. 15, 2002

(30) Foreign Application Priority Data
Dec. 11, 2001 (TW) 090130852

(51) Int. Cl. H01L 27/15

(52) U.S. Cl. 257/79

(57) ABSTRACT

The present invention is to provide an organic electroluminescent device with a containing fluorine inorganic layer whose structure sequentially comprises a substrate, a transparent conductive layer (anode), a containing fluorine inorganic layer, a hole-transport layer, an organic light-emitting layer, an electron-transport layer, and a metallic conductive layer (cathode), wherein said a containing inorganic layer is made of metallic fluoride, and it can stabilize as well as increase the lifetime for an organic electroluminescent device.

### BACKGROUND OF INVENTION

1. Field of Invention

The present invention is to provide an organic electroluminescent device with a containing fluorine inorganic layer, wherein it utilizes the light-emitting semiconductor device to emit light when a potential is employed, and it belongs to an electroluminescent device (hereinafter referred as “EL device”) field, and is a brand-new displaying technique in the present.

2. Description of Prior Art

Since in 1987 Kodak Company demonstrated an organic molecule-based EL device and in 1990 Cambridge University in United Kingdom also successfully employed the polymer material on an EL device, it has been attracted higher attention and merits of research work.

An organic electroluminescence (OEL) display technique possesses lots of advantages such as self-emitting light, highly responding speed, wide view-angle, high resolution, high brightness, low driven voltage, etc. viewed as a brand-new applied technique for display. The most basic OEL device is a double-layer organic structure device, wherein the first layer is a hole-transport layer and the second layer is an organic light-emitting layer/electron-transport layer, and the double-layer organic materials are placed between a transparent electrode (anode) and a metallic electrode (cathode). In order to improve the luminance efficiency of an OEL device, it also forms a triple-layer organic layer device between a transparent electrode (anode) and a metallic electrode (cathode), wherein the laminated sequence is a hole-transport layer, an organic light-emitting layer, and an electron-transport layer. The light-emitting process of this device is after a potential is applied to an OEL device, in the presence of electric field driving a hole and an electron moves from anode and cathode, respectively, and passes over the corresponding individual energy barrier, and meets together to form an exciton in the light-emitting layer, thereby the light emits in terms of irradiation decayed from the excited state to the ground state. An OEL device demonstrated by Kodak Company in 1987 is the most basic double-layer OEL device, wherein the structure is ITO/NPB/Alq/MgAg, since in this basic double-layer OEL device the energy barrier of Alq and cathode metallic electrode is much higher, thereby the electron-injecting amount is much lower, in order to increase the efficiency of OEL device, to increase the brightness, to decrease the driven voltage, and to extend the long life of device, Kodak Company substituted the cathode metallic electrode with a containing fluorine inorganic composite electrode viewed as an electron-transport layer which can increase the electron-injecting amount, decrease the driven voltage, and increase the brightness, wherein said LiF has the highest value, and usually, LiF/Al is employed in the composite electrode. However, in this report they just only improved an interface between a light-emitting layer and a cathode metallic electrode but did not deal with an interface between a transparent electrode (anode) and a hole-transport layer. If it attempts to deposit with evaporation a hole-injection layer (e.g. CuPc) between a transparent electrode and a hole-transport layer to increase the hole-injecting amount, it causes to increase the driven voltage.

### SUMMARY OF THE INVENTION

Hence, the aim of this invention is to solve the drawbacks described above. In order to avoid the presence of the drawbacks described above, the present invention is to provide an OEL device with a containing fluorine inorganic layer, wherein to improve the stability of OEL device it places a containing fluorine inorganic layer between a transparent electrode and a hole-transport layer to increase the current of the device, to decrease the driven voltage, and to extend the device life.

In order to obtain the aim described above, the present invention is to provide an OEL device with a containing fluorine inorganic layer, wherein between a transparent electrode (anode) and a metallic electrode (cathode) it sequentially forms a containing fluorine inorganic layer, a hole-transport layer, an organic light-emitting layer, and an electron-transport layer. A containing fluorine inorganic layer between the anode and a hole-transport layer deposited a metallic fluoride with evaporation can enhance the current of OEL device, decrease the driven voltage, and extend the device life.

### BRIEF DESCRIPTION OF THE DRAWINGS

Detailed description and technique contents of this invention will be described by the accompanying drawings as follows:

FIG. 1 illustrates the structure of an OEL device with a containing fluorine inorganic layer for the present invention.

FIG. 2 is a current-voltage comparative diagram for ITO/NPB/Alq/LiF/Al and ITO/AlF3/NPB/Alq/LiF/Al two devices.

FIG. 3 is a brightness-voltage comparative diagram for ITO/NPB/Alq/LiF/Al and ITO/AlF3/NPB/Alq/LiF/Al two devices.

FIG. 4 is a diagram of AlF3 film thickness vs. device efficiency in ITO/AlF3/NPB/Alq/LiF/Al.

FIG. 5 is a brightness decay-time comparative diagram for ITO/NPB/Alq/LiF/Al and ITO/AlF3/NPB/Alq/LiF/Al two devices.

FIG. 6 is a voltage increase-time comparative diagram for ITO/NPB/Alq/LiF/Al and ITO/AlF3/NPB/Alq/LiF/Al two devices.

FIG. 7 is a brightness decay-time comparative diagram for ITO/CuPc/Alq/LiF/Al and ITO/AlF3/NPB/Alq/LiF/Al two devices.

FIG. 8 is a voltage increase-time comparative diagram for ITO/CuPc/Alq/LiF/Al and ITO/AlF3/NPB/Alq/LiF/Al two devices.

FIG. 9 is a brightness decay-time comparative diagram for ITO/NPB/Alq/LiF/Al and ITO/MFx/NPB/Alq/LiF/Al two devices.

### DETAILED DESCRIPTION OF THE INVENTION

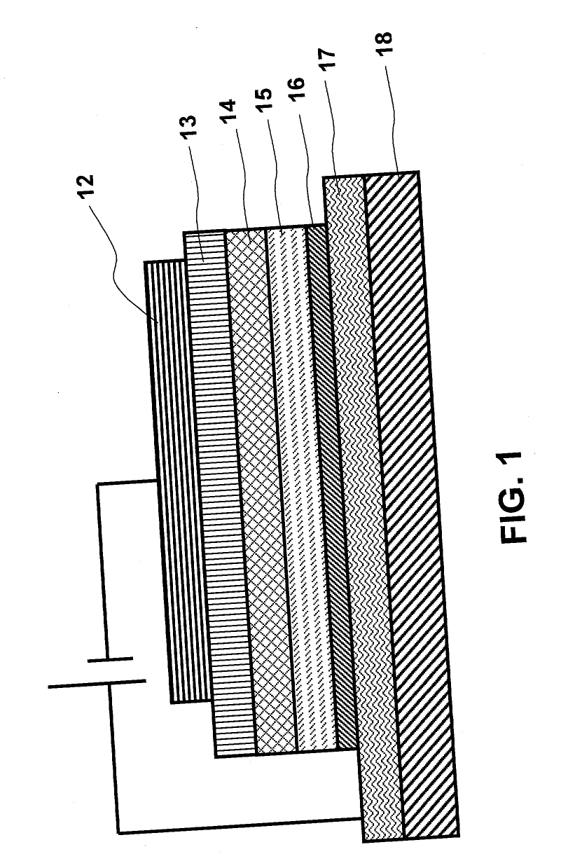

The present invention is to provide an OEL device with a containing fluorine inorganic layer whose structure is shown as in FIG. 1. Firstly, it provides a substrate layer 18, an electric insulating layer and photo-transmitting material, the photo-transmitting property is to transmit this substrate layer 18 when an OEL device emits the light, thereby usually, is a glass or a plastic. On the substrate layer 18 it forms a transparent electrode 17 viewed as the EL device anode electrode, usually, is to employ indium tin oxide or indium zinc oxide, this layer is capable of transmitting when an OEL device emits the light, thereby it possesses the conductive and photo-transmitting properties.

On the transparent electrode it deposits with evaporation to form a containing fluorine inorganic layer 16 with thickness of in the range between 5 and 500 A, the function of this layer is to increase the hole-injecting amount, and the material for this containing fluorine inorganic layer 16 can be a metallic fluoride such as AlF3, MgF2, CaF2, SrF2, BaF2, LiF, NaF, KF, RbF, CsF, etc.

On this containing fluorine inorganic layer it deposits with evaporation to form a hole-transport layer 15 whose material can be N,N′-diphenyl-N,N′-(m-tolyl)benzidine (TPD) or N,N′-bis-(1-naphenyl)-N,N′-diphenyl-1′-biphenyl-4,4′-diamine (NPB). Then, on the hole-transport layer it forms an organic light-emitting layer whose material is a fluorescent light-emitting material, which can let the electron and the hole recombine in this area to emit the light. The simplest structure is a single light-emitting material such as tris-(8-hydroxyquinoline)aluminum (Alq) mostly be used, this material possesses highly fluorescent efficiency, and is a green light-emitting material. An organic light-emitting layer also can be composed of a variety of materials, in which it includes a host material and one or several kinds of guest materials. The host material usually employs Alq, and the guest material is a fluorescent material also called as dopant, which can control an OEL color.

On an organic light-emitting layer 14 it forms an electron-transport layer 13 whose material can be Alq or a containing oxadiazole group compound such as 2-(4-biphenyl)-5-(4-tert-butylphenyl) -1,3,4-oxadiazole (PBD). Alq possesses the light-emitting and electron-transport properties, thereby in an OEL device of the present invention an organic light-emitting layer 14 and an electron-transport layer all employ Alq. Finally, on an electron-transport layer 13 it forms a metallic electrode 12 viewed as a cathode of the OEL device, in which the material usually employs a layer of lower work function and a layer of stabilized metal in air, and also employs a double-layer structure composite electrode such as LiF/Al.

### EXAMPLE 1

### Device 1

Wash an ITO glass substrate as follows: firstly, wash it with detergent, place it in an ultrasonic vessel be vibrated using pure water and isopropyl alcohol twice, respectively, and then dry it in an oven. After drying, place an ITO glass substrate on the carrier plate, place in the chamber for the plasma treatment.

Firstly, on an ITO glass substrate sequentially it is evaporated with a hole-transport layer, NPB (600 A), an organic light-emitting layer/an electron-transport layer, Alq (600 A), LiF (5 A), and Al (1000 A) as a cathode metallic electrode. After finish the device fabrication place it in the dry box for the package and the device property test. An initial voltage of the device is 2.6 V, at 10 V the current density and brightness is 170 mA/cm2 and 6020 cd/m2, respectively. The highest efficiency of the device is 3.0 lm/W. The measurement condition for the lifetime is to measure the brightness decay at 20 mA/cm2 of the constant current density driving.

### EXAMPLE 2

### Device 2

Wash an ITO glass substrate as follows: firstly, wash it with detergent, place it in an ultrasonic vessel be vibrated using pure water and isopropyl alcohol twice, respectively, and then dry it in an oven. After drying, place an ITO glass substrate on the carrier plate, place in the chamber for the plasma treatment.

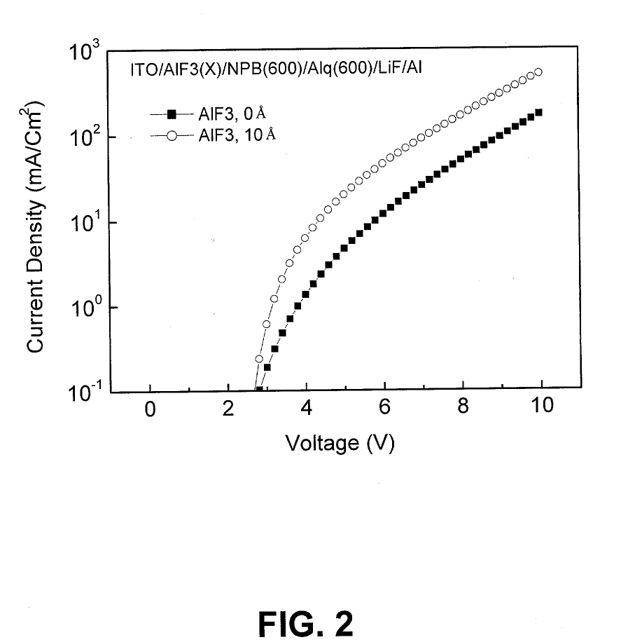

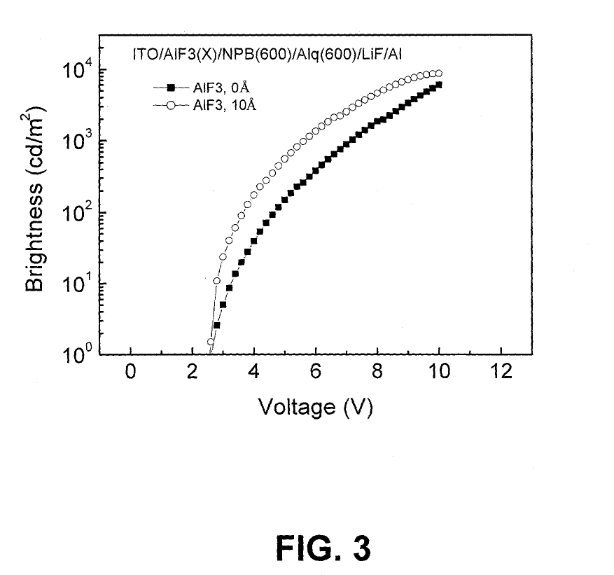

Firstly, on an ITO glass substrate sequentially it is evaporated with AlF3 (10 A), a hole-transport layer, NPB (600 A), an organic light-emitting layer/an electron-transport layer, Alq (600 A), LiF (5 A), and Al (1000 A) as a cathode metallic electrode. After finish the device fabrication place it in the dry box for the package and the device property test. An initial voltage of the device is 2.6 V, at 10 V the current density and brightness is 507 mA/cm2 and 8697 cd/m2, respectively. The highest efficiency of the device is 2.8 lm/W. FIG. 2 and FIG. 3 illustrate the current density and brightness of the device 2 are higher than those of the device 1.

### EXAMPLE 3

### Device 3

Wash an ITO glass substrate as follows: firstly, wash it with detergent, place it in an ultrasonic vessel be vibrated using pure water and isopropyl alcohol twice, respectively, and then dry it in an oven. After drying, place an ITO glass substrate on the carrier plate, place in the chamber for the plasma treatment. Firstly, on an ITO glass substrate sequentially it is evaporated with AlF3 (30 A), a hole-transport layer, NPB (600 A), an organic light-emitting layer/an electron-transport layer, Alq (600 A), LiF (5 A), and Al (1000 A) as a cathode metallic electrode. After finish the device fabrication place it in the dry box for the package and the device property test. An initial voltage of the device is 2.6 V, and the highest efficiency of the device is 3.2 lm/w.

### EXAMPLE 4

### Device 4

Wash an ITO glass substrate as follows: firstly, wash it with detergent, place it in an ultrasonic vessel be vibrated using pure water and isopropyl alcohol twice, respectively, and then dry it in an oven. After drying, place an ITO glass substrate on the carrier plate, place in the chamber for the plasma treatment.

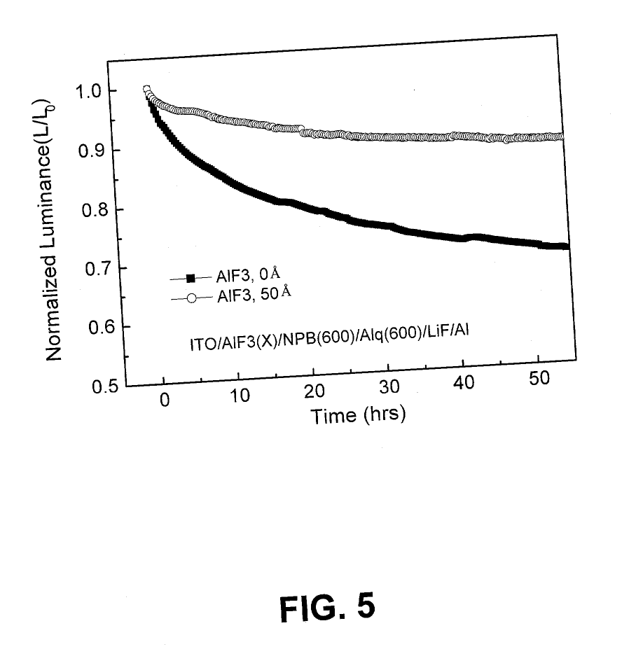

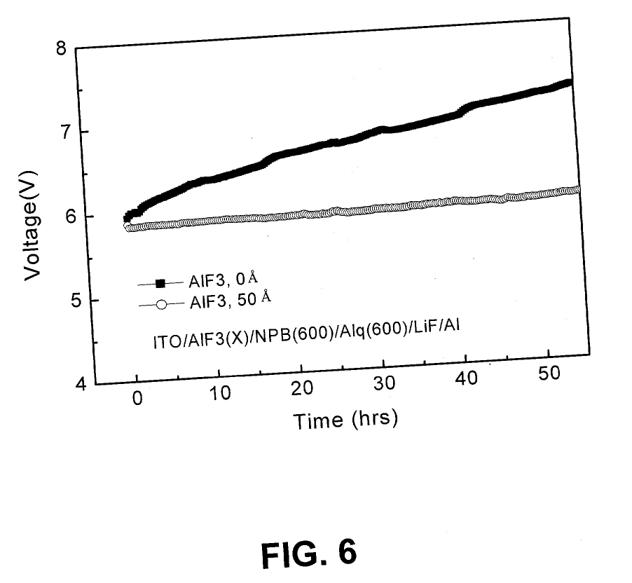

Firstly, on an ITO glass substrate sequentially it is evaporated with AlF3 (50 A), a hole-transport layer, NPB (600 A), an organic light-emitting layer/an electron-transport layer, Alq (600 A), LiF (5 A), and Al (1000 A) as a cathode metallic electrode. After finish the device fabrication place it in the dry box for the package and the device property test. An initial voltage of the device is 2.6 V, and the highest efficiency of the device is 2.9 lm/W. FIG. 5 is a comparative lifetime for the device 1 and the device 4, at 20 mA/cm2 of the constant current density the brightness for two devices is about 600 cd/m2, FIG. 5 indicates the brightness decay rate of the device 4 is slower than that of the device 1, it means the device 4 is much more stable. FIG. 6 also illustrates the results during increasing the voltage, it indicates the device 4 is quite stable.

### EXAMPLE 5

### Device 5

Wash an ITO glass substrate as follows: firstly, wash it with detergent, place it in an ultrasonic vessel be vibrated using pure water and isopropyl alcohol twice, respectively, and then dry it in an oven. After drying, place an ITO glass substrate on the carrier plate, place in the chamber for the plasma treatment.

Firstly, on an ITO glass substrate sequentially it is evaporated with AlF3 (75 A), a hole-transport layer, NPB (600 A), an organic light-emitting layer/an electron-transport layer, Alq (600 A), LiF (5 A), and Al (1000 A) as a cathode metallic electrode. After finish the device fabrication place it in the dry box for the package and the device property test. An initial voltage of the device is 2.6 V, and the highest efficiency of the device is 3.2 lm/W.

### EXAMPLE 6

### Device 6

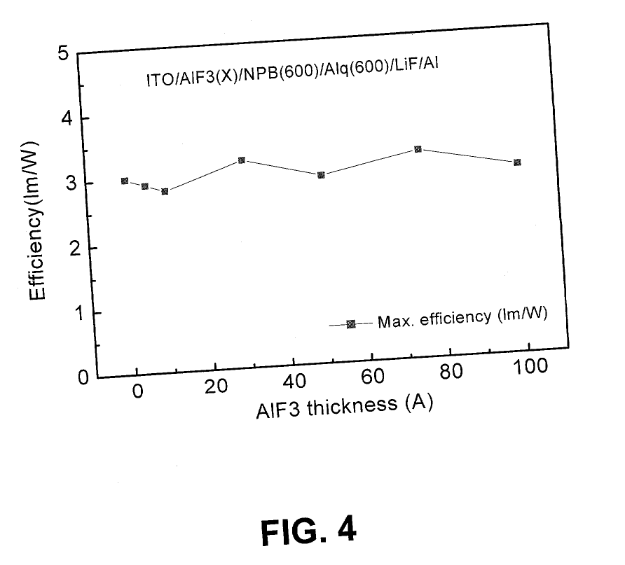

Wash an ITO glass substrate as follows: firstly, wash it with detergent, place it in an ultrasonic vessel be vibrated using pure water and isopropyl alcohol twice, respectively, and then dry it in an oven. After drying, place an ITO glass substrate on the carrier plate, place in the chamber for the plasma treatment. Firstly, on an ITO glass substrate sequentially it is evaporated with AlF3 (100 A), a hole-transport layer, NPB (600 A), an organic light-emitting layer/an electron-transport layer, Alq (600 A), LiF (5 A), and Al (1000 A) as a cathode metallic electrode. After finish the device fabrication place it in the dry box for the package and the device property test. An initial voltage of the device is 2.6 V, and the highest efficiency of the device is 2.9 lm/W. FIG. 4 is a comparative efficiency diagram for the device 1 and the device 6, it indicates the efficiency for the AlF3 film thickness of 30 A and 75 A is higher than that of the device without an AlF3 layer.

### EXAMPLE 7

### Device 7

Wash an ITO glass substrate as follows: firstly, wash it with detergent, place it in an ultrasonic vessel be vibrated using pure water and isopropyl alcohol twice, respectively, and then dry it in an oven. After drying, place an ITO glass substrate on the carrier plate, place in the chamber for the plasma treatment.

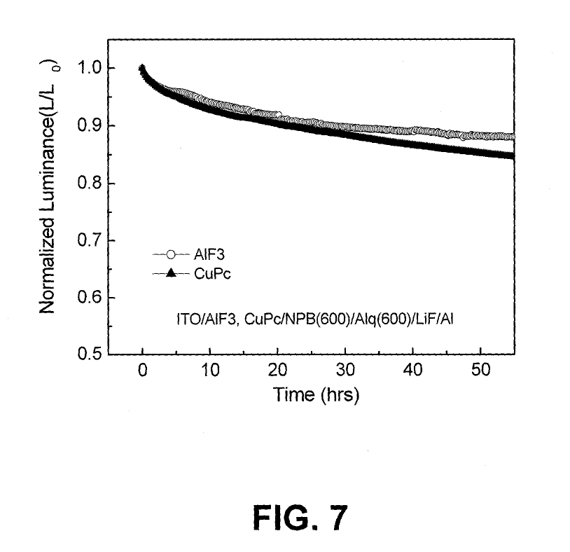

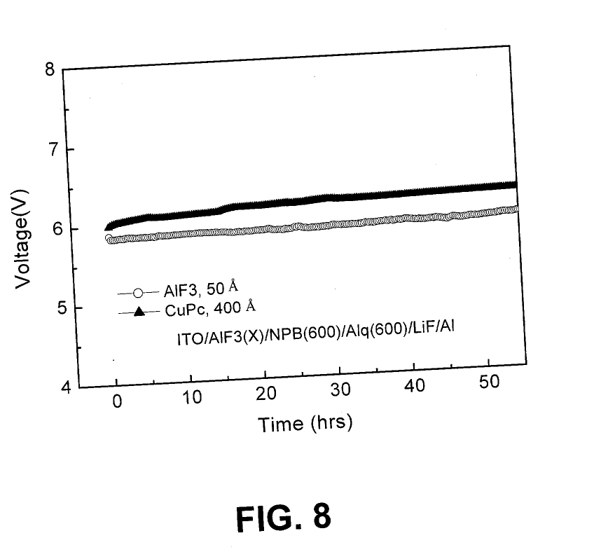

Firstly, on an ITO glass substrate sequentially it is evaporated with CuPc (400 A), a hole-transport layer, NPB (600 A), an organic light-emitting layer/an electron-transport layer, Alq (600 A), LiF (5 A), and Al (1000 A) as a cathode metallic electrode. After finish the device fabrication place it in the dry box for the package and the device property test. An initial voltage of the device is 3.2 V, and the highest efficiency of the device is 2.8 lm/W. FIG. 7 is a comparative lifetime for the device 7 and the device 4, at 20 mA/cm2 of the constant current density the brightness for two devices is about 600 cd/m2, FIG. 5 indicates the brightness decay rate of the device 4 is slower than that of the device 7, it means the device 4 is much more stable. FIG. 8 also illustrates the results during increasing the voltage, it indicates the device 4 is quite stable, and its driven voltage is also lower than that of the device 7.

### EXAMPLE 8

### Device 8

Wash an ITO glass substrate as follows: firstly, wash it with detergent, place it in an ultrasonic vessel be vibrated using pure water and isopropyl alcohol twice, respectively, and then dry it in an oven. After drying, place an ITO glass substrate on the carrier plate, place in the chamber for the plasma treatment. Firstly, on an ITO glass substrate sequentially it is evaporated with CaF2 (50 A), a hole-transport layer, NPB (600 A), an organic light-emitting layer 1 an electron-transport layer, Alq (600 A), LiF (5 A), and Al (1000 A) as a cathode metallic electrode. After finish the device fabrication place it in the dry box for the package and the device property test. An initial voltage of the device is 2.6 V, and the highest efficiency of the device is 2.9 lm/W.

### EXAMPLE 9

### Device 9

Wash an ITO glass substrate as follows: firstly, wash it with detergent, place it in an ultrasonic vessel be vibrated using pure water and isopropyl alcohol twice, respectively, and then dry it in an oven. After drying, place an ITO glass substrate on the carrier plate, place in the chamber for the plasma treatment.

Firstly, on an ITO glass substrate sequentially it is evaporated with MgF2 (50 A), a hole-transport layer, NPB (600 A), an organic light-emitting layer/an electron-transport layer, Alq (600 A), LiF (5 A), and Al (1000 A) as a cathode metallic electrode. After finish the device fabrication place it in the dry box for the package and the device property test. An initial voltage of the device is 2.6 V, and the highest efficiency of the device is 2.3 lm/W.

### EXAMPLE 10

### Device 10

Wash an ITO glass substrate as follows: firstly, wash it with detergent, place it in an ultrasonic vessel be vibrated using pure water and isopropyl alcohol twice, respectively, and then dry it in an oven. After drying, place an ITO glass substrate on the carrier plate, place in the chamber for the plasma treatment.

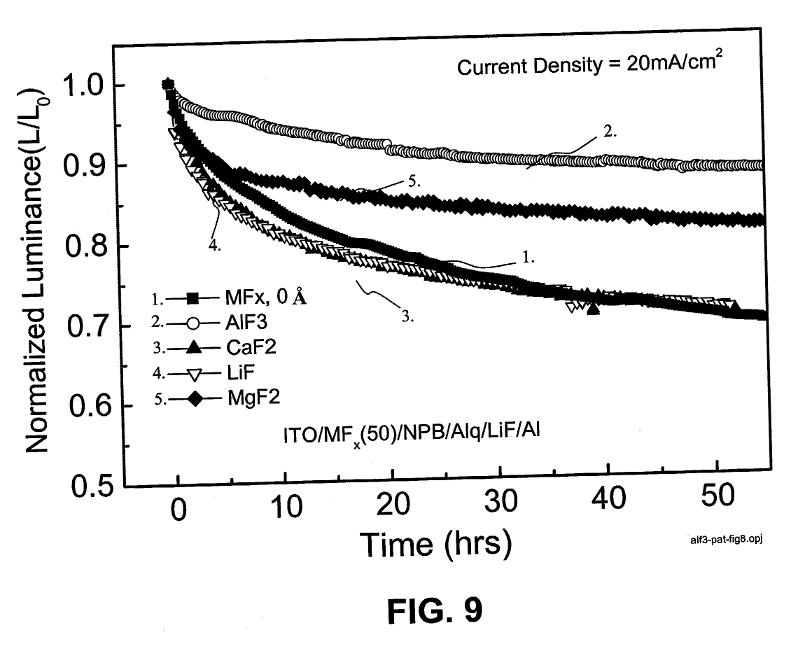

Firstly, on an ITO glass substrate sequentially it is evaporated with LiF (50 A), a hole-transport layer, NPB (600 A), an organic light-emitting layer/an electron-transport layer, Alq (600 A), LiF (5 A), and Al (1000 A) as a cathode metallic electrode. After finish the device fabrication place it in the dry box for the package and the device property test. An initial voltage of the device is 2.6 V, and the highest efficiency of the device is 2.7 lm/W. FIG. 9 is a brightness decay diagram for the device with various metallic fluorides, it indicates the device with various metallic fluorides are quite stable.

What is claimed is:

1. An OEL device with a containing fluorine inorganic layer comprises an anode and a cathode, a hole-transport layer 15, an organic light-emitting layer, and an electro-transport layer between an anode and a cathode, the characteristic is an additional a containing fluorine inorganic layer 16 between an anode and a hole-transport layer 15.

2. An OEL device with a containing fluorine inorganic layer of claim 1 wherein said the anode material is an indium-tin-oxide (ITO) and indium-zinc-oxide (IZO).

3. An OEL device with a containing fluorine inorganic layer of claim 1 wherein said the containing fluorine inorganic layer 16 is a metallic fluoride, which can be selected from LiF, NaF, BeF2, MgF2, CaF2, SrF2, BaF2, AlF3, etc.

4. An OEL device with a containing fluorine inorganic layer of claim 1 wherein said the thickness of the containing fluorine inorganic layer 16 is in the range of 5˜500 A.
